(19) United States
(12) Patent Application Publication
(10) Pub. No.: US 2010/0315853 A1
(43) Pub. Date: Dec. 16, 2010

(54) SEMICONDUCTOR INTEGRATED CIRCUIT

(75) Inventors: Koichiro NOMURA, Osaka (JP); Shoji Sakamoto, Kyoto (JP); Nobuyuki Nakai, Osaka (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/861,598

(22) Filed: Aug. 23, 2010

Related U.S. Application Data
(63) Continuation of application No. PCT/JP2009/001271, filed on Mar. 23, 2009.

(30) Foreign Application Priority Data
May 19, 2008 (JP) 2008-131381

(51) Int. Cl. G11C 5/06; G11C 8/00

(52) U.S. Cl. 365/63; 365/230.03; 365/201

(57) ABSTRACT

In a semiconductor integrated circuit including a memory macro, such as a DRAM, an SRAM, a ROM, a flash memory, or the like, and a logic circuit, memory macro test-dedicated pads are provided on the memory macro, whereby an increase in the number of normal pads is reduced or prevented to reduce or prevent an increase in the chip area. Moreover, by fixing arrangement (positions) of the pads provided on the memory macro between memory macros of a plurality of memory macro-including semiconductor integrated circuits, a single common probe card for a single chip can be used for the memory macro-including semiconductor integrated circuits, thereby providing low-cost testing.

### CROSS-REFERENCE TO RELATED APPLICATIONS

This is a continuation of PCT International Application PCT/JP2009/001271 filed on Mar. 23, 2009, which claims priority to Japanese Patent Application No. 2008-131381 filed on May 19, 2008. The disclosures of these applications including the specifications, the drawings, and the claims are hereby incorporated by reference in their entirety.

### BACKGROUND

The present disclosure relates to semiconductor integrated circuits. More particularly, the present disclosure relates to arrangement of memory macro test pads in a semiconductor integrated circuit including a memory macro.

Conventionally, for memory macro-including semiconductor integrated circuits, the memory macro portion is tested by “probe testing” at the wafer level, in which a plurality of chips are typically simultaneously measured (“simultaneous measurement/test”). Some of normal pads provided at the four outermost circumferential sides of a chip are arbitrarily assigned a role of a test pad for use in probe testing by the designer. However, when test-dedicated pads are provided in this manner, the test-dedicated pads are often distributed at all of the four sides of the chip. As a result, the efficiency of simultaneous measurement cannot be increased, because of arrangement of needles of a probe card used in probe testing, which is a problem.

To solve this problem, there is, for example, a technique in which, as shown in FIG. 6, one or two rows of pads dedicated to testing of the memory macro portion are arranged in parallel and provided in proximity to the memory macro portion, separately from the normal pads provided at the four sides of the chip. As a result, the constraint on arranging probe card needles is eliminated, thereby increasing the efficiency of simultaneous measurement (see, for example, Japanese Patent Publication No. H11-8277).

FIG. 6 shows a conventional semiconductor integrated circuit 100 including a memory macro 101, a logic circuit 102, normal pads 103, and memory macro test-dedicated pads 104. Portions 105 surrounded by dashed lines are memory macro test-dedicated pad arranged regions.

### SUMMARY

With the aforementioned conventional technique, however, although the efficiency of simultaneous measurement is increased, the memory macro test-dedicated pads 104 are further provided in the chip in addition to the normal pads 103 provided at the four outermost circumferential sides of the chip. As a result, the area of the chip is increased by the memory macro test-dedicated pad arranged regions 105 of FIG. 6, which is a problem.

On the other hand, as the number of chips to be simultaneously measured in memory macro testing increases, the cost of producing a probe card for simultaneous measurement increases. The probe card needs to be produced during the diffusion step after the memory macro-including semiconductor integrated circuit has been designed. Therefore, for example, if a circuit design error is found after completion of the diffusion step and therefore the produced probe card for simultaneous measurement is useless, excessive cost occurs.

The present disclosure has been made in view of the aforementioned problems. The detailed description describes implementations of a low-cost memory macro-including semiconductor integrated circuit in which the increase in the chip area is reduced or prevented when memory macro test pads are arranged.

The detailed description also describes implementations of low-cost testing employing a single common probe card for measuring a single chip for a plurality of memory macro-including semiconductor integrated circuits, thereby reducing or avoiding the risk that a high-cost probe card for simultaneous measurement needs to be produced again due to defective circuit design.

In an example memory macro-including semiconductor integrated circuit of the present disclosure, memory macro test pads are provided on the memory macro. As a result, the increase in the chip area is reduced or prevented, thereby providing a low-cost memory macro-including semiconductor integrated circuit.

In an example memory macro-including semiconductor integrated circuit of the present disclosure, arrangement of pads is fixed irrespective of an increase in the memory capacity of the memory macro. Specifically, by fixing arrangement (positions) of memory macro test-dedicated pads on the memory macro, a single common probe card for measuring a single chip can be used in probe testing for various memory macro-including semiconductor integrated circuits having the same memory macro. As a result, the probe card for measuring a single chip can be used to check whether or not there is a defect in circuit design of a memory macro-including semiconductor integrated circuit before a probe card for simultaneous measurement is produced. Thus, the risk that the high-cost probe card for simultaneous measurement needs to be produced again due to defective circuit design circuit can be reduced or avoided. In addition, the single common probe card for measuring a single chip can be used for a plurality of memory macro-including semiconductor integrated circuits, resulting in low-cost testing.

According to the present disclosure, the memory macro test-dedicated pads are provided on the memory macro, whereby an area for providing the memory macro test-dedicated pads does not need to be additionally provided in the chip, and therefore, the increase in the chip area can be reduced or prevented. Moreover, even if the memory capacity of the memory macro is increased, the fixed pad arrangement allows the same probe card to be used in probe testing for a plurality of products including a memory macro. Moreover, pads can be arranged without regard to the chip area or the like, and therefore, a large number of power supply pads and ground pads can be provided. Thus, a low-cost semiconductor integrated circuit and a high-quality memory test environment can be provided.

### BRIEF DESCRIPTION OF THE DRAWINGS

FIG. 1 is a plan view of a semiconductor integrated circuit including a memory macro according to an embodiment of the present disclosure.

FIG. 2 is an enlarged view showing a detailed configuration of a memory macro of FIG. 1.

FIG. 3 is a diagram for describing an interval between each pad in a memory macro-including semiconductor integrated circuit according to another embodiment of the present disclosure.

FIG. 4 is a diagram for describing an interval between each pad in a memory macro-including semiconductor integrated circuit according to another embodiment of the present disclosure.

FIG. 5 is a plan view of a semiconductor integrated circuit including a plurality of memory macros according to another embodiment of the present disclosure.

FIG. 6 is a plan view of a conventional memory macro-including semiconductor integrated circuit.

### DETAILED DESCRIPTION

A semiconductor integrated circuit including a memory macro (e.g., a DRAM, an SRAM, a ROM, a flash memory, etc.) according to an embodiment of the present disclosure will be described with reference to the accompanying drawings.

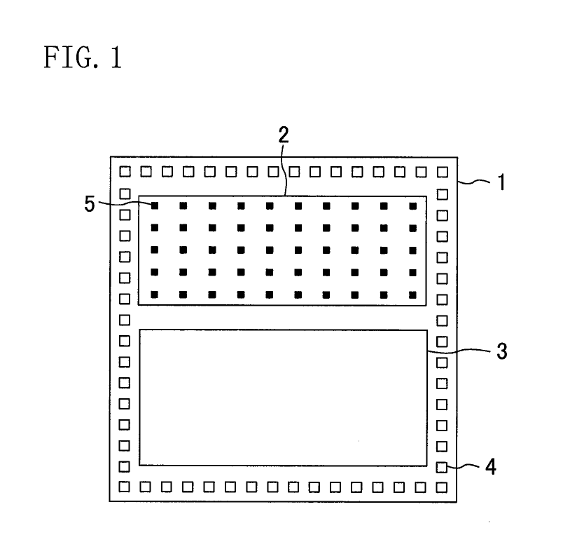

FIG. 1 is a diagram showing a configuration of the memory macro-including semiconductor integrated circuit of the embodiment of the present disclosure. The memory macro-including semiconductor integrated circuit 1 includes a memory macro 2, a logic circuit 3, normal pads 4 provided at four outermost circumferential sides of the memory macro-including semiconductor integrated circuit 1, and memory macro test-dedicated pads 5 provided on the memory macro 2.

As shown in FIG. 1, because the memory macro test-dedicated pads 5 are provided on the memory macro 2, it is no longer necessary to assign some of the normal pads 4 a role of a test-dedicated pad which is used in testing of the memory macro 2. As a result, the number of pads can be reduced, whereby the chip area can be reduced.

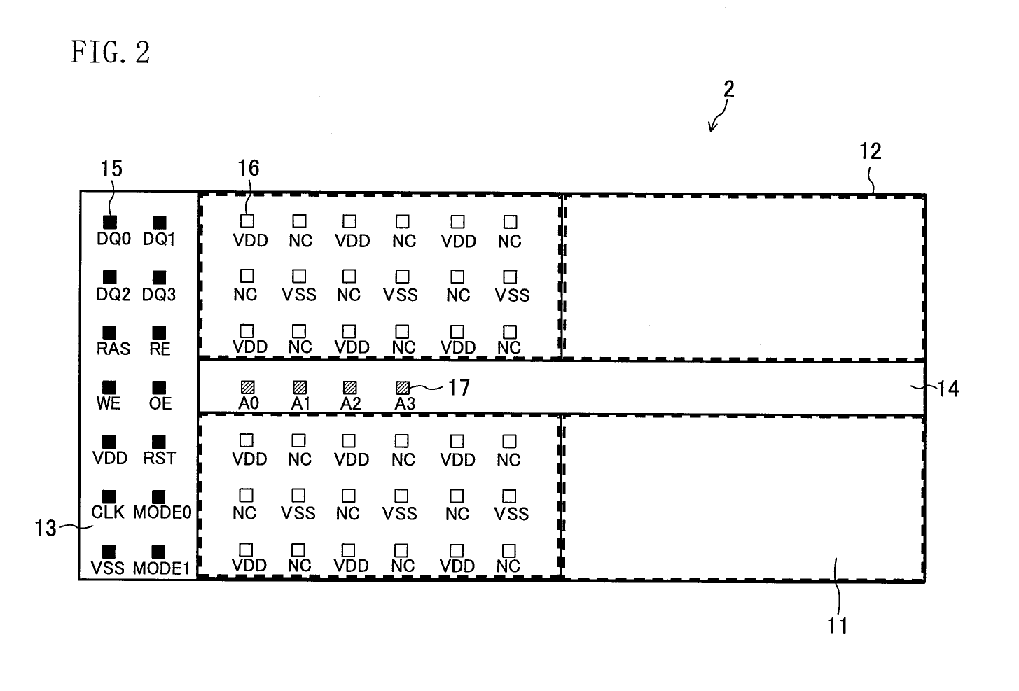

FIG. 2 shows a detailed configuration of the memory macro 2 of FIG. 1 in the embodiment of the present disclosure. The memory macro 2 includes a plurality of sub-memory cell arrays 11 each including a plurality of memory cells (a portion surrounded by a dashed line in FIG. 2), which constitute a memory cell array 12, a control circuit 13 which generates a signal for controlling the memory macro 2, a row decoder 14 which switches row addresses, signal line pads 15 which are provided on the control circuit 13, power supply/ground pads 16 which are provided on the memory cell array 12, and signal pads 17 which are provided on the row decoder 14 and the number of which is increased or decreased as the memory capacity is increased or decreased.

In FIG. 2, reference characters DQ0-DQ3 indicate data input/output terminals. A reference character RAS indicates an RAS signal terminal. A reference character RE indicates a read enable signal terminal. A reference character WE indicates a write enable signal terminal. A reference character OE indicates an output enable signal terminal. A reference character RST indicates a reset terminal. A reference character CLK indicates a clock signal terminal. Reference characters MODE0 and MODE1 indicate test mode switching signal terminals. Reference characters A0-A3 indicate address input terminals. A reference character VDD indicates each of power supply terminals. A reference character VSS indicates each of ground terminals. A reference character NC indicates each of non-connected pins which are not connected to any place. The aforementioned terminal configuration of FIG. 2 is only for illustrative purposes and is not intended to limit the present disclosure.

The memory macro 2 of FIG. 2 can be mounted on the semiconductor integrated circuit 1 of FIG. 1 including a logic circuit. In this case, the memory macro 2 needs to have a memory capacity corresponding to the system of the product. The memory capacity is increased or decreased by increasing or decreasing the number of the sub-memory cell arrays 11. For example, when the memory capacity of a sub-memory cell array 11 is 0.5 Mbits, then if the product needs 2 Mbits, four sub-memory cell arrays 11 are provided, where two of the four sub-memory cell arrays 11 are provided on each of opposite sides (upper and lower sides) of the row decoder 14. Of course, if the number of memory cells is increased, a row decoder 14 which controls the additional memory cells needs to be added. Thus, the capacity required by the product can be satisfied. While the numbers of the sub-memory cell arrays 11 and the like are increased or decreased, depending on the change in the capacity, if the control circuit 13 is originally designed to handle the maximum capacity of the memory macro 2 which can be mounted, the same control circuit 13 can be employed for any products, i.e., the control circuit 13 does not need to be changed, depending on the product.

The signal line pads 15 of FIG. 2 which are required for control of the memory macro 2 are provided on the memory macro control circuit 13 thus configured. Because the circuit area of the control circuit 13 is not changed depending on the memory capacity, arrangement (positions) of the pads can be fixed. The signal pads 17 are provided on the row decoder 14. The number of the signal pads 17 are increased or decreased, depending on the memory capacity. As described above, the circuit scale of the row decoder 14 is increased with an increase in the memory capacity. Therefore, even if the number of required pads 17 is increased due to the increase in the memory capacity, the region of the row decoder 14 is also increased, whereby a place where the additional pads 17 are provided can be ensured. The power supply/ground pads 16 are provided on the sub-memory cell arrays 11. This is because if the signal pads are provided on the memory cells, noise caused by the signal pads varying at a short period affects the memory cells. This is also because a sense amplifier circuit which is generally known as a circuit which reads out and amplifies a minute signal of a memory cell consumes a large amount of current, and therefore, by applying a voltage from the vicinity of the sense amplifier circuit, stable sense operation is achieved.

Although the power supply/ground pads 16 can be provided across the entire memory cell array 12, the power supply/ground pads 16 may be provided only on a portion of the sub-memory cell arrays 11 constituting the memory cell array 12. In the case of the memory macros 2 which have different memory capacities, i.e., different numbers of sub-memory cell arrays 12, and have the same configurations of the control circuit 13 and the row decoder 14, by fixing the portion of the sub-memory cell arrays 11 where the power supply/ground pads 16 are provided, the pads are located at the same positions on the memory macro 2 between each memory macro-including semiconductor integrated circuit 1, and therefore, the same probe card for a single chip can be used to perform probe testing.

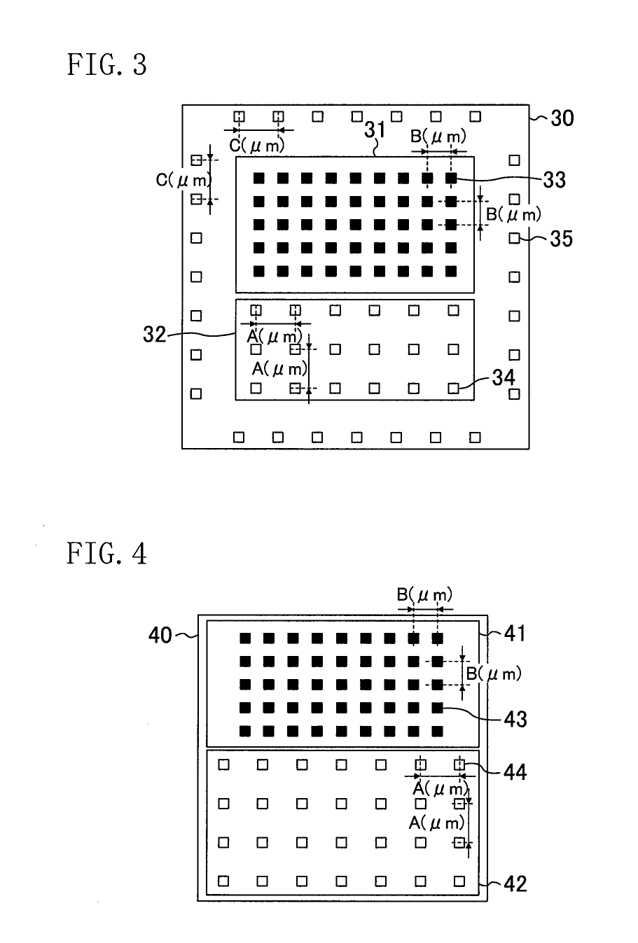

FIG. 3 is a diagram for describing an interval between each pad provided in a memory macro-including semiconductor integrated circuit according to an embodiment of the present disclosure. The memory macro-including semiconductor integrated circuit 30 includes a memory macro 31, a logic circuit 32, memory macro test-dedicated pads 33 provided on the memory macro 31, pads 34 provided on the logic circuit 32, and normal pads 35 provided at four outermost circumferential sides of the memory macro-including semiconductor integrated circuit 30. In FIG. 3, A (μm) is a distance between adjacent pads 34 on the logic circuit 32, B (μm) is a distance between adjacent memory macro test-dedicated pads 33 on the memory macro 31, and C (μm) is a distance between adjacent pads 35 at the four outermost circumferential sides of the memory macro-including semiconductor integrated circuit 30.

The memory macro test-dedicated pads 33 provided on the memory macro 31 do not require a process for connection to the outside, such as wire bonding or the like, in the step of assembly after dicing. Therefore, the interval between each pad which requires connection to the outside during the assembly step, such as the pads 34 provided on the logic circuit 32 and the pads 35 provided at the four outermost circumferential sides of the memory macro-including semiconductor integrated circuit 30, does not need to be equal to the interval between each memory macro test-dedicated pad 33, which is not involved with the assembly step, which does not cause a problem. Similarly, even if the aforementioned three pad intervals have the relationship A≠B≠C, a problem does not arise.

Moreover, even if the shape of a pad which requires connection to the outside during the assembly step, such as the pads 34 provided on the logic circuit 32 and the pads 35 provided at the four outermost circumferential sides of the memory macro-including semiconductor integrated circuit 30, is different from the shape of the memory macro test-dedicated pads 33, which are not involved with the assembly step, a problem does not arise.

FIG. 4 is a diagram for describing the interval between each pad provided in, particularly, a memory macro-including semiconductor integrated circuit according to an embodiment of the present disclosure which includes no pads at the four outermost circumferential sides of the chip, such as the normal pads 35 of FIG. 3. The memory macro-including semiconductor integrated circuit 40 includes a memory macro 41, a logic circuit 42, memory macro test-dedicated pads 43 provided on the memory macro 41, and pads 44 provided on the logic circuit 42. In FIG. 4, A (μm) is a distance between adjacent pads 44 on the logic circuit 42, and B (μm) is a distance between adjacent memory macro test-dedicated pads 43 on the memory macro 41.

The memory macro test-dedicated pads 43 provided on the memory macro 41 do not require a process for connection to the outside, such as wire bonding or the like, in the step of assembly after dicing. Therefore, the interval between each pad which requires connection to the outside during the assembly step, such as the pads 44 provided on the logic circuit 42, does not need to be equal to the interval between each memory macro test-dedicated pad 43, which is not involved with the assembly step, which does not cause a problem.

Moreover, the shape of a pad which requires connection to the outside during the assembly step, such as the pads 44 provided on the logic circuit 42, does not need to be the same as the shape of the memory macro test-dedicated pads 43, which are not involved with the assembly step, which does not cause a problem.

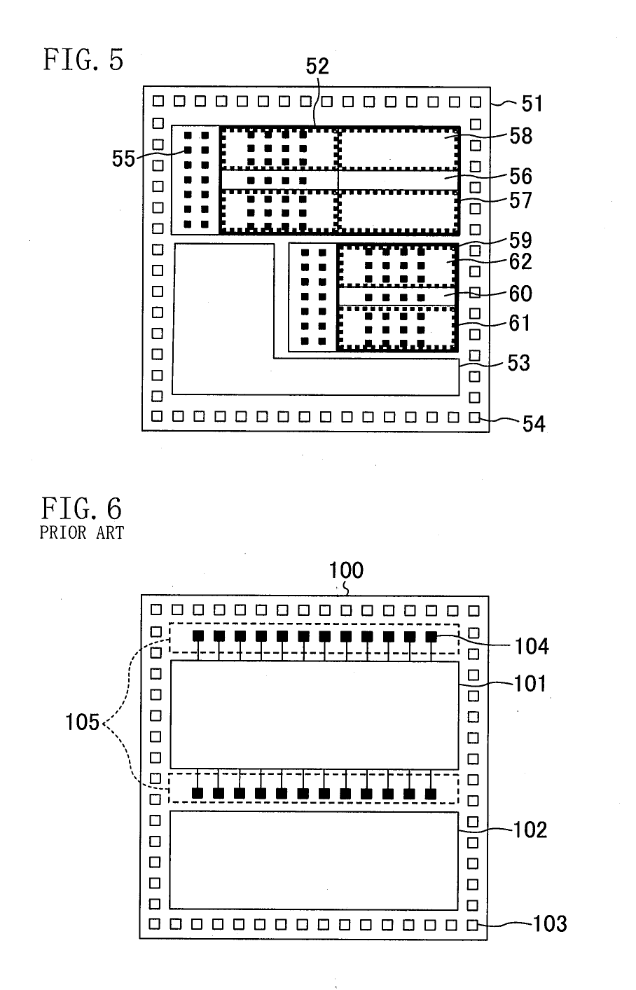

FIG. 5 is a diagram showing a configuration of a memory macro-including semiconductor integrated circuit including a plurality of memory macros according to an embodiment of the present disclosure. The memory macro-including semiconductor integrated circuit 51 includes a first memory macro 52, a logic circuit 53, normal pads 54 provided at four outermost circumferential sides of the chip, memory macro test-dedicated pads 55 provided on memory macros, a row decoder 56 for the memory macro 52, a memory cell array 57 in the memory macro 52, sub-memory cell arrays 58 in the memory macro 52, a second memory macro 59, a row decoder 60 for the memory macro 59, a memory cell array 61 in the memory macro 59, and sub-memory cell arrays 62 in the memory macro 59.

As shown in FIG. 5, even if the memory macro 52 and the memory macro 59 have different memory capacities, by providing the same arrangement (positions) of the pads between these memory macros as described with reference to FIG. 2, a single common probe card for measuring a single chip can be used in probe testing for memory macros of various memory macro-including semiconductor integrated circuits. Moreover, for a similar reason, even if a plurality of memory macros (52 and 59) are provided in a single memory macro-including semiconductor integrated circuit (51) as shown in FIG. 5, by testing each memory macro separately, a single common probe card for measuring a single chip can be used.

Note that the semiconductor integrated circuit 51 including a plurality of memory macros shown in FIG. 5 is only for illustrative purposes and, of course, is not intended to limit the number of memory macros in the present disclosure to two.

As described above, the memory macro test-dedicated pads are provided on the memory macro(s), whereby the number of pads can be reduced and therefore the chip area can be reduced, resulting in a low-cost memory macro-including semiconductor integrated circuit. Moreover, even if the memory macros have different memory capacities, by providing the same arrangement (positions) of pads between the memory macros, a single common probe card for measuring a single chip can be used for all the memory macros, whereby the risk that a defect occurs during production of a high-cost probe card for simultaneous measurement can be reduced or avoided, resulting in low-cost testing.

In the semiconductor integrated circuit of the present disclosure, the memory macro test-dedicated pads are provided on the memory macro(s), and therefore, an area for providing the memory macro test-dedicated pads does not need to be additionally provided, resulting in a reduction in the chip area of the semiconductor integrated circuit. Therefore, the present disclosure is useful for providing low-cost semiconductor integrated circuits.

What is claimed is:

1. A semiconductor integrated circuit comprising:
a semiconductor memory device including
at least one sub-memory cell array including memory cells arranged in a matrix,
a memory cell array including the at least one sub-memory cell array,
a control circuit configured to control the memory cell array, and
a row decoder configured to control row addresses; and
pads provided on the semiconductor memory device and configured to test the semiconductor memory device.

2. The semiconductor integrated circuit of claim 1, wherein some of the pads are provided on the memory cell array.

3. The semiconductor integrated circuit of claim 2, wherein the pads provided on the memory cell array are substantially equally spaced.

4. The semiconductor integrated circuit of claim 3, wherein the pads provided on the memory cell array are power supply/ground pads.

5. The semiconductor integrated circuit of claim 4, wherein at least one of the power supply/ground pads provided on the memory cell array is connected to a power supply or a ground of a sense amplifier circuit.

6. The semiconductor integrated circuit of claim 4, wherein the pads provided on the memory cell array are arranged in a minimum pitch.

7. The semiconductor integrated circuit of claim 1, wherein some of the pads are provided on the control circuit and are signal line pads.

8. The semiconductor integrated circuit of claim 1, wherein some of the pads are provided on the row decoder and are signal pads.

9. The semiconductor integrated circuit of claim 8, wherein the pads provided on the row decoder are signal pads, and the number of the signal pads is increased or decreased, depending on a memory capacity of the semiconductor memory device.

10. A semiconductor integrated circuit comprising:
a plurality of memory blocks each including a plurality of memory cells arranged in a matrix; and
a logic block including a random logic, wherein
the plurality of memory blocks and the logic block are formed on a semiconductor substrate, and
positions of pads provided on each of the plurality of memory blocks are the same between each of the plurality of memory blocks.

11. A semiconductor integrated circuit comprising:
a memory block including memory cells arranged in a matrix; and
a logic block including a random logic, wherein
the memory block and the logic block are formed on a semiconductor substrate, and
pads provided on the memory block and pads provided on the logic block have different intervals between adjacent pads.

12. A semiconductor integrated circuit comprising:
a memory block including memory cells arranged in a matrix; and
a logic block including a random logic, wherein
the memory block and the logic block are formed on a semiconductor substrate, and
pads provided on the memory block and pads provided on the logic block have different shapes.

13. An electrical apparatus employing a semiconductor integrated circuit, wherein
the semiconductor integrated circuit includes
a memory block including memory cells arranged in a matrix,
a logic block including a random logic, and
a memory block test-dedicated pad provided on the memory block, wherein
the memory block and the logic block are formed on a semiconductor substrate, and
the memory block test-dedicated pad provided on the memory block is not connected to the electrical apparatus.
